(19) United States
(12) Patent Application Publication
(10) Pub. No.: US 2026/0118181 A1
(43) Pub. Date: Apr. 30, 2026

(54) LIGHT DETECTION ELEMENT

(71) Applicant: TDK CORPORATION, Tokyo (JP)

(72) Inventors: Tomohito MIZUNO, Tokyo (JP); Hideaki FUKUZAWA, Tokyo (JP); Tetsuya SHIBATA, Tokyo (JP)

(73) Assignee: TDK CORPORATION, Tokyo (JP)

(21) Appl. No.: 19/371,308

(22) Filed: Oct. 28, 2025

(30) Foreign Application Priority Data
Oct. 27, 2025 (JP) 2025-180111
Oct. 29, 2024 (JP) 2024-189833

(51) Int. Cl. G01J 5/10

(52) U.S. Cl. CPC G01J 5/10

(57) ABSTRACT

The light detection element 100 includes a magnetic element 10 including a first ferromagnetic layer 1 and a second ferromagnetic layer 2 to which light is irradiated, and a spacer layer 3 sandwiched between the first ferromagnetic layer 1 and the second ferromagnetic layer 2, an upper electrode 11 in contact with the upper surface 1a of the first ferromagnetic layer 1, and a lower electrode 20 in contact with the lower surface 2a of the second ferromagnetic layer 2. The lower electrode 20 has a narrowed plan view shape of the connection region 22 including the portion 20a in contact with the second ferromagnetic layer 2 and includes a heat sink layer 13 having a thickness that functions as a heat sink, and the entire magnetic element 10 including the upper electrode 11 is covered with a thermal conductive insulating material 31.

### CROSS-REFERENCE TO RELATED APPLICATION

This application claims a priority, under the Paris Convention, to Japanese Patent Application No. 2024-189833 filed on October 29, 2024, and Japanese Patent Application No. 2025-180111 filed on October 27, 2025, the entirety of which is incorporated herein by reference.

### TECHNICAL FIELD

The present disclosure relates to a light detection element.

### BACKGROUND

Light electric conversion elements such as light detection elements are used in a variety of applications. For example, Japanese Patent Application Publication No. 2001-292107 (JP 2001-292107 A) describes a receiver that receives optical signals using a photodiode. The photodiode is, for example, a pn junction diode using a semiconductor pn junction and converts light into an electrical signal.

Furthermore, for example, Japanese Patent Application Publication No. 2022-069387 (JP 2022-069387 A) discloses a light detection element using a magnetic element, and a receiver capable of high-speed optical communication using this light detection element. Japanese Patent Application Publication No. 2022-111043 (JP 2022-111043 A) discloses a light detection element using a magnetic element with excellent heat dissipation properties, and a receiver using this light detection element.

FIG. 10A is a cross-sectional view showing the schematic configuration of a light detection element 200 described in JP 2022-111043 A as an example of a conventional spin photodetector, and FIG. 10B is a plan view of its lower electrode 120. As shown in FIG. 10A, the light detection element 200 comprises a lower electrode 120, a magnetic element 10, and an upper electrode 11 in this order on a substrate 40. The magnetic element 10 includes a first ferromagnetic layer 1, a second ferromagnetic layer 2, a spacer layer 3 sandwiched between the first ferromagnetic layer 1 and the second ferromagnetic layer 2, and a cap layer 4. The periphery of the side of the magnetic element 10 is covered with an insulator 25.

However, as recognized by the present inventors, the conventional light detection element 200 shown in FIG. 10A is low in heat dissipation from the upper portion of the light detection element 200 because the air with very low thermal conductivity exists around the upper electrode 11.

Furthermore, as shown in FIG. 10B, the conventional light detection element 200 is configured in such a manner that the lower electrode 120 receives the entire spot S of light irradiated on the connection region 21 including a portion 120a in contact with the second ferromagnetic layer 2 of the magnetic element 10. The size of the connection region 21 is, for example, 6 μm in width A and 4 μm in length B. The diameter of the light spot S is approximately equal to the wavelength of the irradiated light (500 nm to 1 μm), and the magnetic element 10 (<200 nm) is positioned at the center of the irradiated light spot S. The lower electrode 120 has a thickness of, for example, about 50 nm, and although the lower electrode 120 and the substrate 40 are in contact with each other. Actually, however, an alumina layer with low thermal conductivity is inserted therebetween, so that the heat dissipation is low even at the lower portion of the light detection element 200.

As described above, in conventional light detection elements, the thermal conductivity of the material around the magnetic element is low, and the film thickness of the lower electrode is extremely thin from the viewpoint of heat dissipation, so that the heat dissipation cannot be sufficiently accomplished, thereby resulting in problems such as low overall heat dissipation and a long fall time during optical response.

One aspect of the present disclosure is made in consideration of the above problems and has an object to provide a light detection element that can improve heat dissipation, thereby shortening the fall time during optical response.

### SUMMARY

One aspect of the present disclosure provides a light detection element comprises a magnetic element including a first ferromagnetic layer, a second ferromagnetic layer, and a spacer layer sandwiched between the first ferromagnetic layer and the second ferromagnetic layer, an upper electrode in contact with a first surface of the first ferromagnetic layer opposite to the spacer layer, and a lower electrode in contact with a second surface of the second ferromagnetic layer opposite to the spacer layer, the lower electrode having a narrowed plan view shape in the area including a portion in contact with the second ferromagnetic layer, and including a heat sink layer having a thickness that functions as a heat sink, and the entire magnetic element including the upper electrode is covered with a thermal conductive insulating material.

### BRIEF DESCRIPTION OF DRAWINGS

FIG. 1 is A cross-sectional view showing the configuration of a light detection element according to one embodiment of the present disclosure.

FIG. 2A is a plan view of the lower electrode.

FIG. 2B is a perspective view of the lower electrode.

FIG. 3A is a schematic diagram showing how the direction (inclination angle) of magnetization M1 of the first ferromagnetic layer of the magnetic element changes in response to changes in the intensity of the irradiated light.

FIG. 3B is a schematic diagram showing how the direction (inclination angle) of magnetization M1 of the first ferromagnetic layer of the magnetic element changes in response to changes in the intensity of the irradiated light.

FIG. 3C is a schematic diagram showing how the direction (inclination angle) of magnetization M1 of the first ferromagnetic layer of the magnetic element changes in response to changes in the intensity of the irradiated light.

FIG. 4 is a schematic diagram showing the results of simulating the temperature distribution inside the light detection element for four Models with different structures.

FIG. 5 is a graph showing the time change in temperature in the first ferromagnetic layer of the magnetic element for four Models with different structures.

FIG. 6 is a table showing the temperature fall time in the first ferromagnetic layer of the magnetic element for four Models with different structures.

FIG. 7A is a cross-sectional view showing the structure of a model with a Ru heat sink layer.

FIG. 7B is a graph showing the results of simulating the temperature change over time in the first ferromagnetic layer of the magnetic element by changing the thickness of the heat sink layer.

FIG. 8A is a cross-sectional view showing the structure of a model with a Cu heat sink layer.

FIG. 8B is a graph showing the results of simulating the temperature change over time in the first ferromagnetic layer of the magnetic element by changing the thickness of the heat sink layer.

FIG. 9 is a graph comparing the temperature changes over time in the first ferromagnetic layer of the magnetic element for the cases of the heat sink layer Ru and the heat sink layer Cu.

FIG. 10A is a cross-sectional view showing the structure of a conventional light detection element.

FIG. 10B is a plan view of a lower electrode of the conventional light detection element.

### DETAILED DESCRIPTION

Hereinafter, an embodiment of the present disclosure will be described in detail with reference to the drawings. For ease of understanding, the scale of each part in the drawings may differ from the actual scale. In the xyz Cartesian coordinate system set in the drawings, the x-axis direction and the y-axis direction are horizontal, and the z-axis direction is vertical. The positive direction of the z-axis is also called the upward direction, and the negative direction of the z-axis is also called the downward direction, but this has nothing to do with the direction of gravity. In directions such as parallel, right angle, orthogonal, horizontal, vertical, up and down, left and right, deviations that do not impair the effect of the embodiment are allowed. In addition, "~" indicating a numerical range means that the numerical values written before and after it are included as the lower and upper limits.

Initially, the first embodiment of the present disclosure will be described hereinafter.

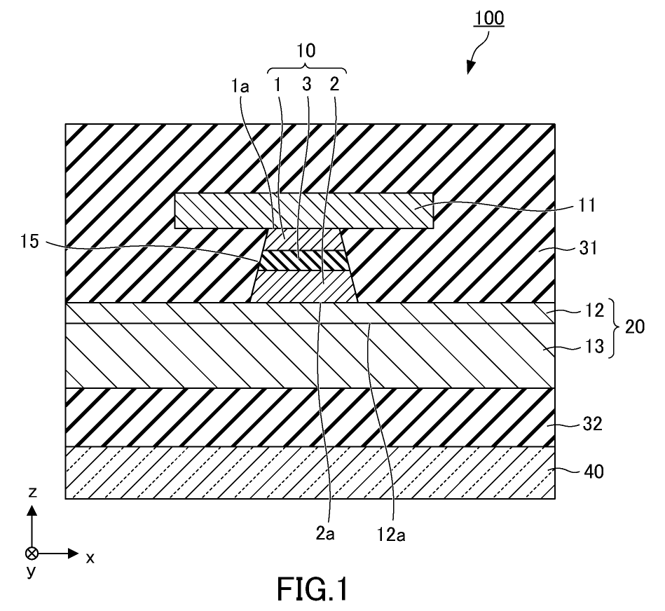

FIG. 1 is a cross-sectional view showing the configuration of a light detection element 100 according to a first embodiment of the present disclosure. As shown in FIG. 1, the light detection element 100 includes a light responsive magnetic element (hereinafter simply referred to as a magnetic element) 10, an upper electrode 11, and a lower electrode 20 on a substrate 40. The magnetic element 10 includes a first ferromagnetic layer 1 to which light is irradiated, a second ferromagnetic layer 2, and a spacer layer 3 sandwiched between the first ferromagnetic layer 1 and the second ferromagnetic layer 2. The upper electrode 11 is provided in contact with the upper surface 1a of the first ferromagnetic layer 1 on the side opposite to the spacer layer 3. The lower electrode 20 is provided in contact with the lower surface 2a of the second ferromagnetic layer 2 on the side opposite to the spacer layer 3. The lower electrode 20 includes a connection region 22 having a portion 20a in contact with the second ferromagnetic layer 2 of the magnetic element 10 and having a narrowed plan view shape, and includes a heat sink layer 13 having a thickness to function as a heat sink. The entire magnetic element 10 including the upper electrode 11, is covered with a thermal conductive insulating material 31.

Light incident on the light detection element 100 is irradiated onto the magnetic element 10. The magnetic element 10 detects the light irradiated onto the magnetic element 10. The magnetic element 10 converts the light irradiated onto the magnetic element 10 into an electrical signal. The light detection element 100 may include a lens that focuses the light onto the magnetic element 10. When the light detection element 100 includes a lens, the magnetic element 10 is disposed, for example, at the focal position of the light focused by the lens. The light detection element 100 may be columnar, for example, prismatic or cylindrical.

The "light" described in this specification is not limited to visible light, and may be infrared light having a wavelength longer than that of the visible light, or ultraviolet light having a wavelength shorter than that of the visible light. The wavelength of the visible light is, for example, 380 nm or more and less than 800 nm. The wavelength of the infrared light is, for example, 800 nm or more and 1 mm or less. The wavelength of the ultraviolet light is, for example, 200 nm or more and less than 380 nm.

Each component will be described hereinafter.

The magnetic element 10 includes at least a first ferromagnetic layer 1, a second ferromagnetic layer 2, and a spacer layer 3 sandwiched between the first ferromagnetic layer 1 and the second ferromagnetic layer 2. In FIG. 1, the second ferromagnetic layer 2, the spacer layer 3, and the first ferromagnetic layer 1 are laminated in this order in the positive direction of the z-axis to form a laminate 15. The laminate 15 constituting the magnetic element 10 may further include other layers such as a third ferromagnetic layer, a buffer layer, a seed layer, a magnetic coupling layer, and a perpendicular magnetization induction layer if necessary.

As shown in FIG. 1, an upper electrode 11 is formed on the upper portion of the laminate 15, and a lower electrode 20 is formed on the lower portion of the laminate 15. When the magnetic element 10 is called as such, the magnetic element 10 may include the upper electrode 11 and the lower electrode 20 other than the laminate 15.

The magnetic element 10 is, for example, a magnetic tunnel junction (MTJ) element in which the spacer layer 3 is made of an insulating material. In this case, the magnetic element 10 can exhibit a tunnel magnetoresistance (TMR) effect. The resistance value of the magnetic element 10 changes when irradiated with light from the outside. The resistance value of the magnetic element 10 in the z-axis direction (resistance value when a current is passed in the z-axis direction) changes in response to the relative change of the state of the magnetization M1 of the first ferromagnetic layer 1 and the state of the magnetization M2 of the second ferromagnetic layer 2. For example, the resistance value of the magnetic element 10 in the z-axis direction changes in response to the change in the relative angle of the direction of the magnetization M1 of the first ferromagnetic layer 1 and the direction of the magnetization M2 of the second ferromagnetic layer 2. Furthermore, for example, the resistance value of the magnetic element 10 in the z-axis direction changes in response to the change in the magnitude of the magnetization M1 of the first ferromagnetic layer 1.

Furthermore, for example, when the spacer layer 3 is made of a metal, the magnetic element 10 can exhibit a giant magnetoresistance (GMR) effect. Such an element is called a GMR element. When the magnetic element 10 is a GMR element, the resistance value in the z-axis direction (resistance value when a current is passed in the z-axis direction) changes in response to the relative change of the state of the magnetization M1 of the first ferromagnetic layer 1 and the state of the magnetization M2 of the second ferromagnetic layer 2. The magnetic element 10 may be called differently an MTJ element, a GMR element, or the like, depending on the material of the spacer layer 3, but is collectively called a magnetoresistance effect element. The total thickness of the magnetic element 10 is, for example, 15 nm to 40 nm.

The magnetic element 10 may have a ferromagnetic material whose magnetization state changes when irradiated with light, and the magnetic element 10 may be formed by any material if its resistance value changes in response to the change in the magnetization state of the magnetic element 10. For example, an anisotropic magnetoresistance (AMR) effect element, a colossal magnetoresistance (CMR) effect element, or the like may be used for the magnetic element 10 in addition to the above-mentioned MTJ element and GMR element.

When light is incident on the light detection element 100 through a lens, the magnetic element 10 is disposed at the focal position of the light in the used band focused by the lens. The focal position of the light in the used band preferably overlaps, for example, with the first ferromagnetic layer 1. For example, when visible light is used, the magnetic element 10 is disposed at the focal position of light in a specific wavelength range of 380 nm or more and less than 800 nm. For example, when infrared light is used, the magnetic element 10 is disposed at the focal position of light in a specific wavelength range of 800 nm or more and less than 1 mm. For example, when ultraviolet light is used, the magnetic element 10 is disposed at the focal position of light in a specific wavelength range of 200 nm or more and less than 380 nm.

The first ferromagnetic layer 1 is a light detection layer whose magnetization state changes when light is irradiated from the outside. The first ferromagnetic layer 1 is sometimes called a magnetization free layer. The magnetization free layer is a layer containing a magnetic material whose magnetization state changes when a specific external energy is applied thereto. The predetermined external energy includes, for example, light irradiated from the outside, a current flowing in the z-axis direction of the magnetic element 10, an external magnetic field, or the like. The state of the magnetization M1 of the first ferromagnetic layer 1 changes depending on the intensity of the irradiated light.

The first ferromagnetic layer 1 is made of a ferromagnetic material. The first ferromagnetic layer 1 contains at least any one of magnetic elements such as Co, Fe, or Ni. The first ferromagnetic layer 1 may contain magnetic elements such as B, Mg, Hf, and Gd in addition to the magnetic elements described above. The first ferromagnetic layer 1 may be, for example, an alloy including a magnetic element and a nonmagnetic element. The first ferromagnetic layer 1 may be composed of multiple layers. The first ferromagnetic layer 1 is, for example, a CoFeB alloy, a laminate in which a CoFeB alloy layer is sandwiched between Fe layers, or a laminate in which a CoFeB alloy layer is sandwiched between CoFe layers. In general, "ferromagnetism" includes "ferrimagnetism". The first ferromagnetic layer 1 may exhibit ferrimagnetism. Alternatively, the first ferromagnetic layer 1 may exhibit ferromagnetism that is not ferrimagnetism. For example, a CoFeB alloy exhibits ferromagnetism that is not ferrimagnetism.

The first ferromagnetic layer 1 may be an in-plane magnetized film having an easy axis of magnetization in the in-plane direction (any direction in the xy plane) or a perpendicular magnetized film having an easy axis of magnetization in the direction perpendicular to the film plane (z-axis direction).

The film thickness of the first ferromagnetic layer 1 is, for example, 1 nm to 5 nm. The film thickness of the first ferromagnetic layer 1 is preferably, for example, 1 nm to 2 nm. When the first ferromagnetic layer 1 is a perpendicular magnetized film, if the film thickness of the first ferromagnetic layer 1 is thin, the effect of applying perpendicular magnetic anisotropy from the layers above and below the first ferromagnetic layer 1 is strengthened, and the perpendicular magnetic anisotropy of the first ferromagnetic layer 1 is enhanced. In other words, if the perpendicular magnetic anisotropy of the first ferromagnetic layer 1 is high, the force that causes the magnetization M1 to return to the z-axis direction is strengthened. On the other hand, if the thickness of the first ferromagnetic layer 1 is thick, the effect of applying perpendicular magnetic anisotropy from the layers above and below the first ferromagnetic layer 1 is relatively weakened, and the perpendicular magnetic anisotropy of the first ferromagnetic layer 1 is weakened.

If the thickness of the first ferromagnetic layer 1 is thin, the volume of the ferromagnetic layer is reduced, and if the thickness of the first ferromagnetic layer 1 is thick, the volume of the ferromagnetic layer is increased. The responsiveness of the magnetization of the first ferromagnetic layer 1 when external energy is applied is inversely proportional to the product (KuV) of the magnetic anisotropy (Ku) and the volume (V) of the first ferromagnetic layer 1. In other words, if the product of the magnetic anisotropy and the volume of the first ferromagnetic layer 1 is reduced, the responsiveness to light is increased. From this viewpoint, to increase the responsiveness to light, it is preferable to appropriately design the magnetic anisotropy of the first ferromagnetic layer 1 and then to reduce the volume of the first ferromagnetic layer 1.

If the thickness of the first ferromagnetic layer 1 is larger than 2 nm, an insertion layer made of, for example, Mo or W may be provided in the first ferromagnetic layer 1. That is, the first ferromagnetic layer 1 may be a laminate in which a ferromagnetic layer, an insertion layer, and a ferromagnetic layer are laminated in this order in the z-axis direction. By the interfacial magnetic anisotropy at the interface between the insertion layer and the ferromagnetic layer, the perpendicular magnetic anisotropy of the entire first ferromagnetic layer 1 is increased. The thickness of the insertion layer is, for example, 0.1 nm to 1.0 nm.

The second ferromagnetic layer 2 is a magnetization fixed layer. The magnetization fixed layer is a layer made of a magnetic material in which the state of magnetization in the magnetization fixed layer is more difficult to change than that of the magnetization free layer when a specific external energy is applied thereto. For example, the magnetization direction of the magnetization fixed layer is more difficult to change than that of the magnetization free layer when a specific external energy is applied thereto. Furthermore, for example, the magnitude of magnetization of the magnetization fixed layer is more difficult to change than that of the magnetization free layer when a predetermined external energy is applied thereto. The coercive force of the second ferromagnetic layer 2 is, for example, larger than that of the first ferromagnetic layer 1. The second ferromagnetic layer 2 has a magnetization easiness axis in the same direction as that of the first ferromagnetic layer 1. The second ferromagnetic layer 2 may be an in-plane magnetized film or a perpendicular magnetized film.

The material of the second ferromagnetic layer 2 is, for example, the same as that of the first ferromagnetic layer 1. The second ferromagnetic layer 2 may be formed by, for example, multilayer films in which Co having a thickness of 0.4 nm to 1.0 nm and Pt having a thickness of 0.4 nm to 1.0 nm are alternately laminated several times. The second ferromagnetic layer 2 may be, for example, a laminate in which Co with a thickness of 0.4 nm to 1.0 nm, Mo with a thickness of 0.1 nm to 0.5 nm, a CoFeB alloy with a thickness of 0.3 nm to 1.0 nm, and Fe with a thickness of 0.3 nm to 1.0 nm are laminated in this order.

The spacer layer 3 is a layer disposed between the first ferromagnetic layer 1 and the second ferromagnetic layer 2. The spacer layer 3 is constituted by a layer composed of a conductor, an insulator, or a semiconductor, or a layer containing in an insulator a current-carrying point composed of a conductor. The spacer layer 3 is, for example, a nonmagnetic layer. The thickness of the spacer layer 3 can be adjusted depending on the orientation directions of the magnetization of the first ferromagnetic layer 1 and the magnetization of the second ferromagnetic layer 2 in the initial state described later.

When the spacer layer 3 is made of an insulating material, a material containing aluminum oxide, magnesium oxide, titanium oxide, silicon oxide, or the like can be used as the material of the spacer layer 3. These insulating materials may also contain elements such as Al, B, Si, and Mg, or magnetic elements such as Co, Fe, and Ni. By adjusting the thickness of the spacer layer 3 to generate a high TMR effect between the first ferromagnetic layer 1 and the second ferromagnetic layer 2, a high magnetoresistance change rate can be obtained. To efficiently utilize the TMR effect, the thickness of the spacer layer 3 may be about 0.5 nm to 5.0 nm, or about 1.0 nm to 2.5 nm.

When the spacer layer 3 is made of a nonmagnetic conductive material, conductive materials such as Cu, Ag, Au, and Ru can be used. To efficiently utilize the GMR effect, the thickness of the spacer layer 3 may be about 0.5 nm to 5.0 nm, or about 2.0 nm to 3.0 nm.

When the spacer layer 3 is made of a nonmagnetic semiconductor material, materials such as zinc oxide, indium oxide, tin oxide, germanium oxide, gallium oxide, or indium tin oxide (ITO) can be used. In this case, the thickness of the spacer layer 3 may be about 1.0 nm to 4.0 nm.

When a layer including a current-carrying point formed by a conductor in a nonmagnetic insulator is used as the spacer layer 3, a structure including a current-carrying point formed by a nonmagnetic conductor such as Cu, Au, or Al in a nonmagnetic insulator formed by aluminum oxide or magnesium oxide may be used. Furthermore, the conductor may be formed by a magnetic element such as Co, Fe, or Ni. In this case, the thickness of the spacer layer 3 may be about 1.0 nm to 2.5 nm. The current-carrying point is, for example, a columnar body with a diameter of 1 nm to 5 nm when viewed from a direction perpendicular to the film surface.

The upper electrode 11 is disposed, for example, in contact with the upper surface 1a of the first ferromagnetic layer 1 on the side opposite to the spacer layer 3. Incident light is irradiated from the upper electrode 11 to the magnetic element 10 and is irradiated at least to the first ferromagnetic layer 1. The upper electrode 11 is made of a material that has electrical conductivity. The upper electrode 11 is, for example, a transparent electrode that is transparent to light in the used wavelength range. The upper electrode 11 preferably transmits, for example, 80% or more of light in the used wavelength range. The upper electrode 11 is, for example, an oxide such as indium tin oxide (ITO), indium zinc oxide (IZO), zinc oxide (ZnO), or indium gallium zinc oxide (IGZO). The upper electrode 11 may have a configuration in which a plurality of metal columns are included in a transparent electrode material of these oxides.

It is not essential to use the above-mentioned transparent electrode material as the upper electrode 11, and a metal material such as Au, Cu, or Al may be used with a thin film thickness, thereby allowing the irradiated light to reach the first ferromagnetic layer 1. When a metal is used as the material of the upper electrode 11, the film thickness of the upper electrode 11 is, for example, 3 nm to 10 nm. The upper electrode 11 may also have an anti-reflection film on the irradiation surface to which light is irradiated.

The lower electrode 20 includes a seed layer (also called a lower electrode layer) 12 on the side in contact with the magnetic element 10, and a heat sink layer 13 in contact with the lower surface 12a of the seed layer 12 on the side opposite to the magnetic element 10. The seed layer 12 of the lower electrode 20 is disposed, for example, to be in contact with the lower surface 2a of the second ferromagnetic layer 2 on the side opposite to the spacer layer 3. The seed layer 12 is made of a material that has electrical conductivity. The seed layer 12 includes, for example, either or both of layers of Ru and Cu, or includes a laminated film of Cu and a metal other than Cu. In addition, the seed layer 12 may be, for example, a laminated film of Ru, Cu, Ru, Cu and Ru, a laminated film of Ru, Cu, Cu and Ru, a laminated film of Cu having a face-centered cubic (fcc) crystal structure and Co having a body-centered cubic (bcc) crystal structure, a laminated film of Cu having an fcc crystal structure and Mo or W having a bcc crystal structure, a laminated film of Cu and Mo, a laminated film of Cu, Co and Mo, or a laminated film of Cu, Co and Mo having a bcc crystal structure. The laminated film of Ru, Cu, Cu and Ru may be, for example, a laminated film of Ru (7.5 nm), Cu (7.5 nm), Cu (7.5 nm) and Ru (7.5 nm) (total thickness 30 nm) in terms of thickness, the laminated film of Cu and Mo may be a laminated film of Cu (15 nm) and Mo (5 nm) in terms of thickness, and the laminated film of Cu, Co and Mo having a bcc crystal structure may be a laminated film of Cu (20 nm), Co (5 nm) and Mo having a bcc crystal structure (5 nm) in terms of thickness. The seed layer 12 may also be a laminated film of Ta or Ti above and below these metals Ru and Cu. A laminated film of Cu and Ta, a laminated film of Ta, Cu and Ti, or a laminated film of Ta, Cu and TaN may also be used. TiN or TaN may also be used as the seed layer 12. The seed layer 12 is, for example, Ru with a thickness of 50 nm (500 Å).

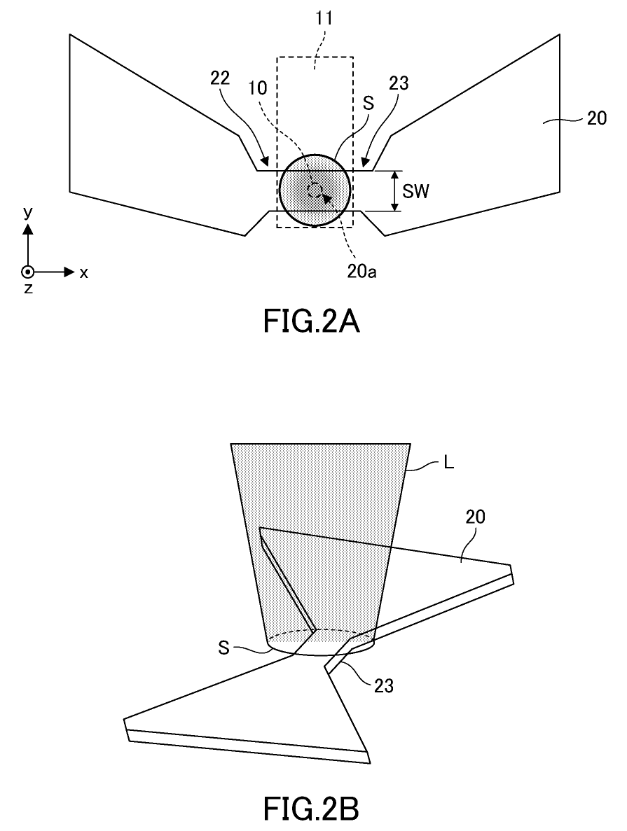

FIG. 2A is a plan view of the lower electrode 20, and FIG. 2B is a perspective view thereof. As shown in FIGS. 2A and 2B, the lower electrode 20 has a connection region 22 of a narrowed plan view shape including a portion 20a that is in contact with the second ferromagnetic layer 2 of the magnetic element 10. The narrowed width SW of the lower electrode 20 is smaller than the diameter of the spot S of the irradiated light L. The portion 20a that is in contact with the second ferromagnetic layer 2 of the magnetic element 10 in the connection region 22 of the lower electrode 20 is, for example, located at the center of the narrowed width and at the center of the spot S of the irradiated light L.

The lower electrode 20 includes, for example, a heat sink layer 13 having a thickness that functions as a heat sink. The heat sink layer 13 includes, for example, either or both of layers of Ru and Cu, or includes a laminated film of Cu and a metal other than Cu. The material constituting the heat sink layer 13 may be the same as or different from that of the seed layer 12. The heat sink layer 13 may be, for example, a laminated film of Ru, Cu, Ru, Cu, and Ru, a laminated film of Ru, Cu, Cu, and Ru, a laminated film of Cu having an fcc crystal structure and Co having a bcc crystal structure, a laminated film of Cu having an fcc crystal structure and Mo or W having a bcc crystal structure, a laminated film of Cu and Mo, a laminated film of Cu, Co, and Mo, or a laminated film of Cu, Co, and Mo having a bcc crystal structure. The laminated film of Ru, Cu, Cu and Ru may be a laminated film of Ru (7.5 nm), Cu (7.5 nm), Cu (7.5 nm) and Ru (7.5 nm) (total thickness 30 nm) in terms of thickness, the laminated film of Cu and Mo may be a laminated film of Cu (15 nm) and Mo (5 nm) in terms of thickness, and the laminated film of Cu, Co and Mo having a bcc crystal structure may be a laminated film of Cu (20 nm), Co (5 nm) and Mo having a bcc crystal structure (5 nm) in terms of thickness. In addition, the heat sink layer 13 may be a laminated film of Ta or Ti above and below these metals Ru and Cu. In addition, a laminated film of Cu and Ta, a laminated film of Ta, Cu and Ti, or a laminated film of Ta, Cu and TaN may be used. In addition, TiN or TaN may be used as the seed layer 12. The thickness of the heat sink layer 13 is, for example, 100 nm or more and 1000 nm or less.

The thermal conductive insulating layer 31 is provided to cover the entire magnetic element 10 including the upper electrode 11. A substrate 40 is provided on the side of the lower electrode 20 opposite to the magnetic element 10, and a thermal conductive insulating layer 32 made of the same material as or different from the material of the thermal conductive insulating layer 31 is provided between the lower electrode 20 and the substrate 40. The thermal conductive insulating layers 31 and 32 are, for example, an insulator. The thermal conductive insulating layers 31 and 32 include, for example, either or both AlN and AlON. The thermal conductive insulating layers 31 and 32 have, for example, a thermal conductivity higher than that of the magnetic element 10. The thermal conductive insulating layers 31 and 32 have, for example, a thermal conductivity higher than that of the upper electrode 11. The thermal conductive insulating layers 31 and 32 have, for example, a thermal conductivity higher than that of the lower electrode 20. The thermal conductivity of the thermal conductive insulating layers 31 and 32 is, for example, larger than 40 W/m·K. A part of the heat generated in the magnetic element 10, the upper electrode 11, and the lower electrode 20 is discharged through the thermal conductive insulating layers 31 and 32.

The thermal conductive insulating layer 31 transmits light in the used band. For example, the thermal conductive insulating layer 31 preferably transmits 80% or more of light in the used wavelength range.

As described above, the light detection element 100 according to the first embodiment can convert light into an electrical signal by replacing the light irradiated to the magnetic element 10 with an output voltage from the magnetic element 10. In addition, the presence of the thermal conductive insulating layers 31 and 32 with high thermal conductivity on the outside of the magnetic element 10, which generates heat in response to irradiation with light, can promote heat dissipation from the magnetic element 10. In other words, after the irradiation of light to the first ferromagnetic layer 1 is stopped, the magnetic element 10 is quickly cooled, and the magnetization M1 quickly returns to the initial state. If the magnetization M1 of the first ferromagnetic layer 1 quickly returns to the initial state, the response characteristics of the light detection element 100 to light are improved. In other words, the response of the light detection element 100 to light is accelerated.

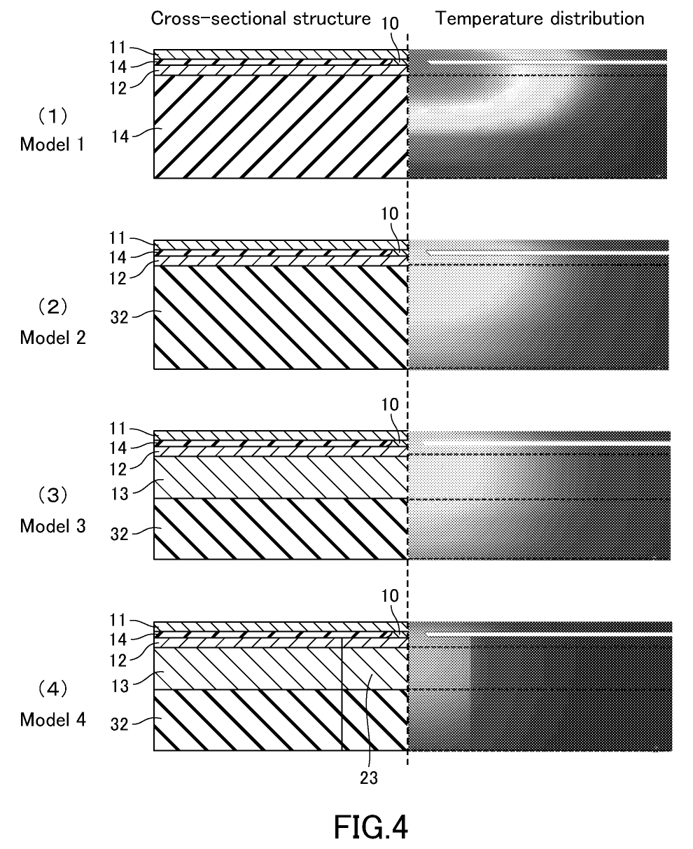

FIG. 4 shows the results of simulating the temperature distribution in the light detection element 100 at a specified time after irradiation with short pulse light for four Models with different structures.

(1) Model 1 is a conventional example and has a structure including, in the positive direction of the z-axis, an insulating layer 14 (k-Al2O3, thermal conductivity 6.9 W/m·K), a lower electrode layer 12 (Ru, thickness 50 nm), a magnetic element 10, and an upper electrode 11 in this order. The magnetic element 10 is surrounded by an insulating layer 14.

(2) Model 2 is a structure including, in the positive direction of the z-axis, a thermal conductive insulating layer 32 (AlN, thermal conductivity 46.5 W/m·K), a lower electrode layer 12 (Ru, thickness 50 nm), a magnetic element 10, and an upper electrode 11 in this order. The magnetic element 10 is surrounded by an insulating layer 14.

(3) Model 3 is a structure including, in the positive direction of the z-axis, a thermal conductive insulating layer 32 (AlN, thermal conductivity 46.5 W/m·K), a heat sink layer 13 (Ru, thickness 200 nm), a lower electrode layer 12 (Ru, thickness 50 nm), a magnetic element 10, and an upper electrode 11 in this order. The magnetic element 10 is surrounded by an insulating layer 14.

(4) Model 4 is a structure including, in the positive direction of the z-axis, a thermal conductive insulating layer 32 (AlN, thermal conductivity 46.5 W/m·K), a heat sink layer 13 (Ru, thickness 200 nm), a lower electrode layer 12 (Ru, thickness 50 nm), a magnetic element 10, and an upper electrode 11 in this order, and the lower electrode 20 consisting of the lower electrode layer 12 and the heat sink layer 13 has a narrowed portion 23. The magnetic element 10 is surrounded by an insulating layer 14.

As can be seen from FIG. 4, the temperature around the magnetic element 10 decreases and the temperature rise range narrows in the following order: Model 1, which is a conventional example; Model 2 with a thermal conductive insulating layer 32 of AlN; Model 3 with a thermal conductive insulating layer 32 of AlN and a heat sink layer 13; and Model 4 with a thermal conductive insulating layer 32 of AlN and a heat sink layer 13 and a narrowed portion 23 in the lower electrode 20. That is, Model 4 has the best heat dissipation performance, followed by Model 3, then Model 2. Model 1 has the worst heat dissipation performance.

FIG. 5 shows the results of simulating the change in temperature over time of the first ferromagnetic layer 1 of the magnetic element 10 when irradiated with short pulse light for five Models with different structures. Models 1 to 4 are the same as FIG. 4. Model 5 has the Ru heat sink layer 13 of Model 4 replaced with a Cu heat sink layer 13. That is, Model 5 includes a thermal conductive insulating layer 32 (AlN, thermal conductivity 46.5 W/m·K), a heat sink layer 13 (Cu, thickness 200 nm), a lower electrode layer 12 (Ru, thickness 50 nm), a magnetic element 10, and an upper electrode 11 in the positive direction of the z axis, in this order, and is a structure in which the lower electrode 20 consisting of the lower electrode layer 12 and the heat sink layer 13 has a narrowed portion 23.

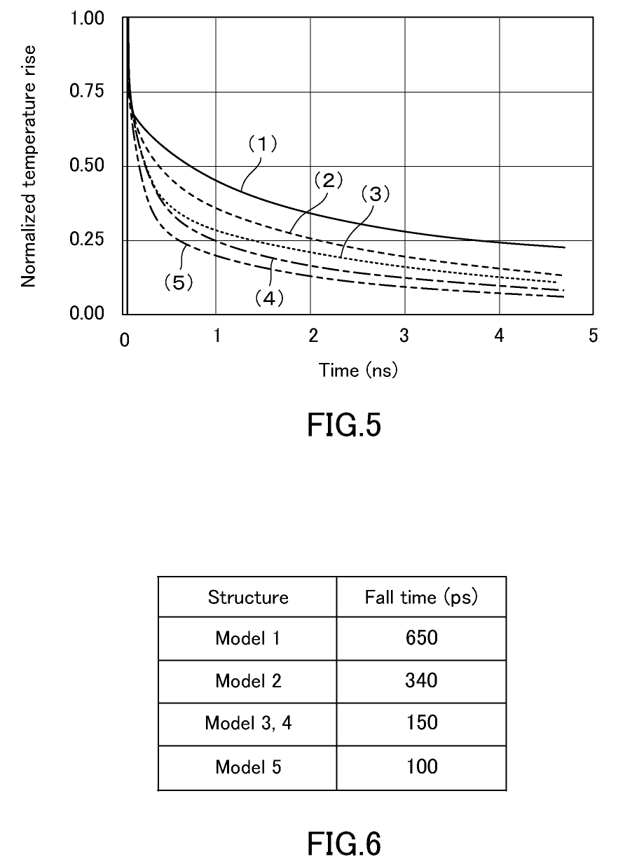

FIG. 6 is a table showing the fall time for the temperature to fall to 1/2 from the state where it has been heated by irradiation with short pulse light for each Model in FIG. 5.

As can be seen from FIG. 5 and FIG. 6, the fall time of the temperature is shortened in the following order: Model 1 which is a conventional example; Model 2 with the AlN thermal conductive insulating layer 32; Model 3 with the AlN thermal conductive insulating layer 32 and the heat sink layer 13; Model 4 with the AlN thermal conductive insulating layer 32 and the Ru heat sink layer 13 and with the lower electrode 20 provided with the narrowed portion 23; and Model 5 with the AlN thermal conductive insulating layer 32 and the Cu heat sink layer 13 and with the lower electrode 20 provided with the narrowed portion 23. In other words, Model 5 has the best heat dissipation performance, followed by Model 4, Model 3, Model 2, and Model 1 has the worst dissipation performance.

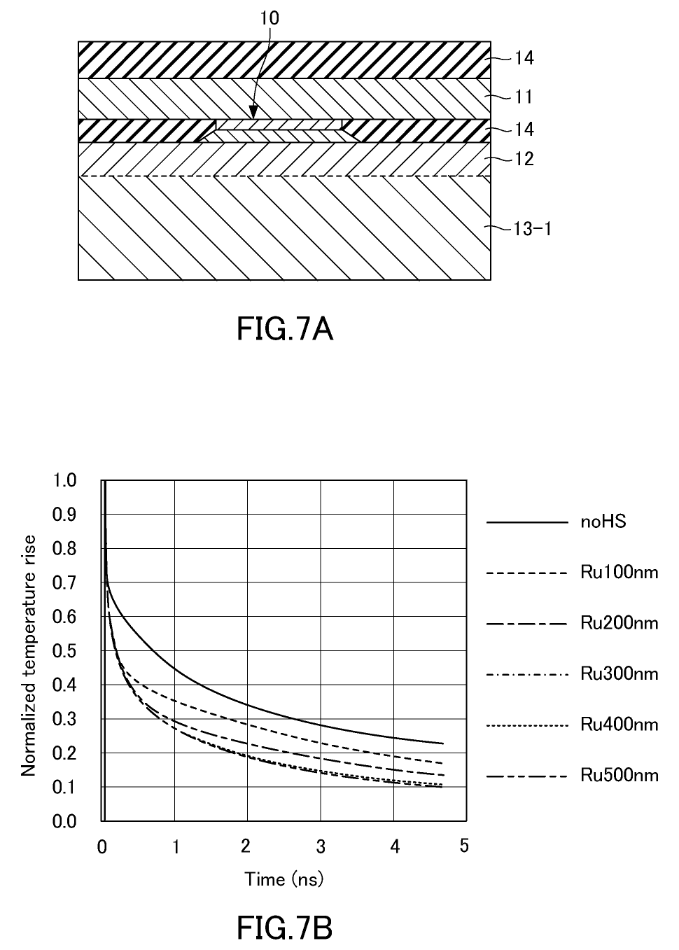

FIG. 7A is a cross-sectional view showing the structure of Model 6 in which the heat sink layer 13-1 is made of Ru, and FIG. 7B is a graph showing the results of simulating the change in temperature over time of the first ferromagnetic layer 1 of the magnetic element 10 by changing the thickness of the heat sink layer 13-1 of Model 6. As shown in FIG. 7A, Model 6 has a heat sink layer 13-1 made of Ru, a lower electrode layer 12 made of Ru and having a thickness of 50 nm, a magnetic element 10, an upper electrode 11 made of ITO, and an insulating layer 14 made of Al2O3 which are laminated in this order in the positive direction of the z-axis, and an insulating layer 14 made of Al2O3 is also embedded around the magnetic element 10.

As shown in FIG. 7B, the temperature fall time becomes shorter as the thickness of the heat sink layer 13-1 increases compared to the case without a heat sink layer (solid line). However, when the thickness of the heat sink layer 13-1 exceeds 300 nm, the heat sink effect appears to be saturated. When the heat sink layer 13-1 of Ru is present, the fall speed (-50% standard) is 150ps. The thickness of the heat sink layer 13-1 may be 100 nm or more and 1000 nm or less, and may be preferably 200 nm.

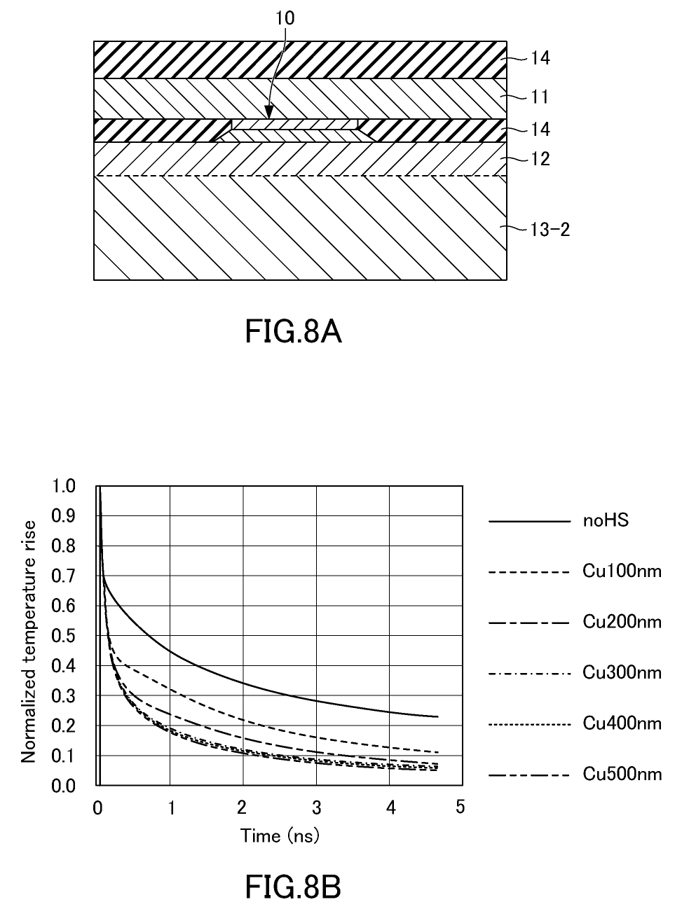

FIG. 8A is a cross-sectional view showing the structure of Model 7 in which the heat sink layer 13-2 is Cu, and FIG. 8B is a graph showing the results of simulating the change in temperature over time of the first ferromagnetic layer 1 of the magnetic element 10 by changing the thickness of the heat sink layer 13-2 of Model 7. As shown in FIG. 8A, Model 7 is Model 6 of FIG. 7A in which the heat sink layer 13-1 of Ru is replaced by the heat sink layer 13-2 of Cu.

As shown in FIG. 8B, the temperature fall time becomes shorter as the thickness of the heat sink layer 13-2 increases, compared to the case in which there is no heat sink layer (solid line). However, as in Model 7 with the Ru heat sink layer 13-1, when the thickness of the Cu heat sink layer 13-2 exceeds 300 nm, the heat sink effect appears to be saturated. When the heat sink layer 13-2 is Cu, the fall time (-50% standard) is 100ps, which is faster than when the heat sink layer 13-1 is Ru. The thickness of the heat sink layer 13-2 may be 100 nm or more and 1000 nm or less, and preferably 200 nm.

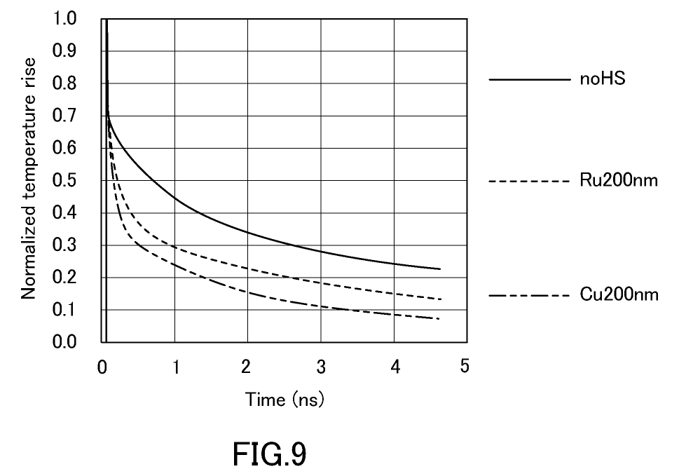

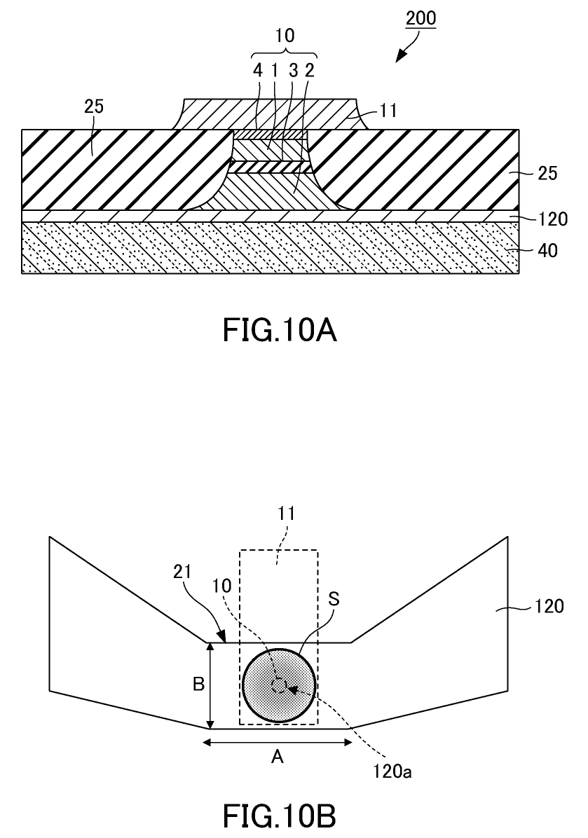

FIG. 9 is a graph comparing the changes in temperature over time in the magnetic element 10 when the heat sink layer 13 (thickness 200 nm) is Ru and when the heat sink layer 13 is Cu. For comparison, the case without the heat sink layer (solid line) is also shown. The fall speed is faster when the heat sink layer 13 is Cu than when the heat sink layer 13 is Ru. Therefore, if the magnetic element 10 can withstand annealing at 400°C, the Cu heat sink layer 13 is preferable than the Ru heat sink layer 13.

The light detection element 100 is obtained by sequentially forming a thermal conductive insulating layer 32, a heat sink layer 13, a lower electrode layer (seed layer) 12, a magnetic element 10, an upper electrode 11, and a thermal conductive insulating layer 31 in this order on a substrate 40.

The magnetic element 10 is manufactured by a process of laminating each layer, an annealing process, a processing process, or the like. First, a thermal conductive insulating layer 32, a heat sink layer 13, a lower electrode layer 12, a second ferromagnetic layer 2, a spacer layer 3, and a first ferromagnetic layer 1 are laminated on an Si substrate 40 in this order. Each layer is formed by, for example, sputtering.

Then, the laminated film is annealed. The annealing temperature is, for example, 250°C to 400°C. After that, the laminated film is processed into a columnar laminate 15 by photolithography and etching (ion milling, etc.). The laminate 15 may be entirely or individually mesa-shaped, cylindrical, prismatic, truncated conical, truncated pyramidal, or the like. The shortest width of the laminate 15 as viewed from the z-axis direction is, for example, 10 nm to 1000 nm.

Next, the thermal conductive insulating layer 31 is formed to cover the side surfaces of the laminate 15. The thermal conductive insulating layer 31 may be laminated plural times. Next, the upper surface 1a of the first ferromagnetic layer 1 is exposed from the thermal conductive insulating layer 31 by chemical mechanical polishing, and an upper electrode layer is formed on the first ferromagnetic layer 1 and the thermal conductive insulating layer 31 by sputtering. The upper electrode layer is processed by photolithography and etching into a column shaped or plate shaped upper electrode 11, for example, in a cylindrical shape, a rectangular column shape, a truncated cone shape, a truncated pyramid shape, or the like. Next, the thermal conductive insulating layer 31 is embedded around and above the upper electrode 11. The above process can obtain a light detection element 100. In this way, the light detection element 100 can be continuously formed by a vacuum film-forming process.

Next, the operation of the light detection element 100 according to the first embodiment will be described hereinafter.

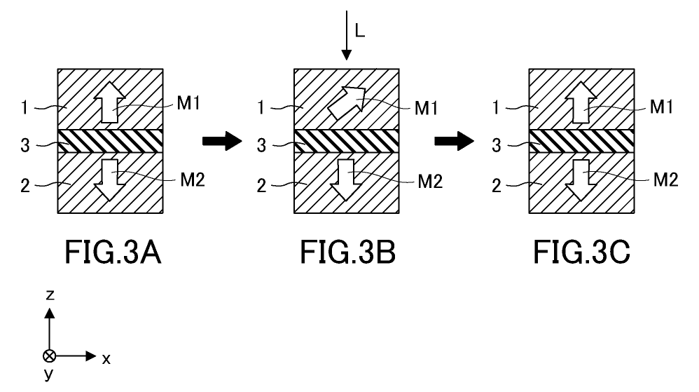

FIGS. 3A, 3B, and 3C are schematic diagrams showing how the direction (tilt angle) of the magnetization M1 of the first ferromagnetic layer 1 of the magnetic element 10 changes in response to changes in the intensity of the irradiated light. FIG. 3A shows the magnetization state of the magnetic element 10 in the initial state, and FIG. 3B shows the magnetization state of the magnetic element 10 when light L is incident on the light detection element 100. As shown in FIG. 3A, in the initial state, for example, the magnetization M1 of the first ferromagnetic layer 1 is upward, and the magnetization M2 of the second ferromagnetic layer 2 is downward, so that both magnetizations are in an anti-parallel state. As shown in FIG. 3B, when light L is irradiated to the magnetic element 10, for example, the direction of the magnetization M1 of the first ferromagnetic layer 1 tilts, and the electrical resistance values in the upward and downward directions of the magnetic element 10 changes. This change is detected as a change in the voltage between the upper electrode 11 and the lower electrode 20.

More specifically, light focused through a lens (not shown) forms a light spot S at the focal point of the lens and is irradiated onto the magnetic element 10 of the light detection element 100. The focal point of the lens is located on the magnetic element 10, preferably the first ferromagnetic layer 1.

When the intensity of the light irradiated onto the first ferromagnetic layer 1 changes, the state of the magnetization M1 of the first ferromagnetic layer 1 changes. The state of the magnetization M1 includes, for example, the tilt angle of the magnetization M1 with respect to the z-axis direction, the magnitude of the magnetization M1, or the like.

For example, when the intensity of the light irradiated onto the first ferromagnetic layer 1 increases, the magnetization M1 of the first ferromagnetic layer 1 tilts from its initial state with external energy caused by the light irradiation. The angle between the direction of the magnetization M1 of the first ferromagnetic layer 1 when the first ferromagnetic layer 1 is not irradiated with light and the direction of the magnetization M1 when the first ferromagnetic layer 1 is irradiated with light is, for example, larger than 0° and smaller than 90°. Alternatively, for example, when the intensity of the light irradiated to the first ferromagnetic layer 1 increases, the magnitude of the magnetization M1 decreases.

When the state of the magnetization M1 of the first ferromagnetic layer 1 changes, the resistance value of the magnetic element 10 in the z-axis direction changes by the magnetoresistance effect. When a constant current (sense current) is passed through the magnetic element 10 in the positive or negative direction of the z-axis using the upper electrode 11 and the lower electrode 20, an output voltage is obtained from the magnetic element 10. In other words, when the state of the magnetization M1 of the first ferromagnetic layer 1 changes, the output voltage from the magnetic element 10 also changes.

The intensity of the light irradiated to the first ferromagnetic layer 1 may take two values, for example, a first intensity and a second intensity. The first intensity may be the case when the intensity of the light irradiated to the first ferromagnetic layer 1 is zero. The intensity of the light irradiated to the first ferromagnetic layer 1 may be multi-valued or may change in an analog manner. When the intensity of the incident light is multi-valued, the output voltage of the magnetic element 10 can also be multi-valued, and when the intensity of the light changes in an analog manner, the output voltage of the magnetic element 10 can also change in an analog manner. The difference between these output voltages (resistance values) can be read out from the light detection element 100 as binary, multi-valued, or analog data.

In a state where the first ferromagnetic layer 1 is irradiated with light of a first intensity (hereinafter simply referred to as the "initial state"), the magnetization M1 of the first ferromagnetic layer 1 and the magnetization M2 of the second ferromagnetic layer 2 may be parallel or anti-parallel or may be perpendicular to each other.

When the magnetizations M1 and M2 are parallel in the initial state, a sense current is passed from the first ferromagnetic layer 1 to the second ferromagnetic layer 2. By passing the sense current in this direction, a spin transfer torque in the same direction as the magnetization M2 of the second ferromagnetic layer 2 acts on the magnetization M1 of the first ferromagnetic layer 1, and the magnetizations M1 and M2 become parallel in the initial state. Furthermore, by passing the sense current in this direction, it is possible to prevent the magnetization M1 of the first ferromagnetic layer 1 from reversing during operation.

When the magnetizations M1 and M2 are antiparallel in the initial state, it is preferable to flow the sense current from the second ferromagnetic layer 2 toward the first ferromagnetic layer 1. By flowing the sense current in this direction, a spin transfer torque in the opposite direction to the magnetization M2 of the second ferromagnetic layer 2 acts on the magnetization M1 of the first ferromagnetic layer 1, and the magnetizations M1 and M2 become antiparallel in the initial state.

As described above, as shown in FIG. 3A, when the intensity of the light irradiated to the first ferromagnetic layer 1 is the first intensity (zero in this example), the magnetization M1 of the first ferromagnetic layer 1 and the magnetization M2 of the second ferromagnetic layer 2 are antiparallel and in the initial state. Next, as shown in FIG. 3B, when the intensity of the light irradiated to the first ferromagnetic layer 1 changes to the second intensity, the magnetization M1 of the first ferromagnetic layer 1 tilts from the initial state. Next, as shown in FIG. 3C, when the intensity of the light irradiated to the first ferromagnetic layer 1 returns to the first intensity (zero), a spin transfer torque is applied by the sense current, or the state of the magnetization M1 of the first ferromagnetic layer 1 returns to its original state due to the effect of magnetic anisotropy, and the magnetic element 10 returns to its initial state.

In this way, the light detection element 100 according to the first embodiment can focus light using a lens to form a small-diameter light spot and irradiate the light on the magnetic element 10, thereby making it possible to convert changes in the intensity of the irradiated light into changes in the output voltage from the magnetic element 10. This means that the light detection element 100 can convert light into an electrical signal.

The electron heating by the irradiation with light is an extremely fast phenomenon which can be utilized to change magnetization at high speed. For example, when the magnetic element 10 is irradiated with short-pulse light (e.g., laser light with FWHM: 50 fs), electrons with a small specific heat are heated very quickly, and the magnetization M1 of the first ferromagnetic layer 1 caused by the electron spin also changes very quickly. As a result, the output voltage from the magnetic element 10 rises quickly. On the other hand, after irradiation with short-pulse light, the magnetization of the first ferromagnetic layer 1 returns to its initial state, and the output voltage from the magnetic element 10 also falls to its initial value. However, if the lattice vibration heat of the magnetic element 10 is slowly dissipated even after the irradiation of the short-pulse light is finished, the magnetization of the first ferromagnetic layer 1 returns slowly, and the fall time of the output voltage from the magnetic element 10 also becomes long. Therefore, it is necessary to heighten the heat dissipation of the magnetic element 10 and shorten the fall time during the optical response.

As described above, the light detection element 100 of the first embodiment can improve heat dissipation and shorten the fall time during the optical response.

The light detection element 100 according to the embodiment of the present disclosure can be applied to a light sensor such as an image sensor in which plural light detection elements are arranged one-dimensionally or two-dimensionally. Such a light sensor can be used in information terminal devices such as smartphones, tablets, personal computers, and digital cameras.

The light detection element 100 according to the embodiment of the present disclosure can be applied to a light electric conversion element of a receiver included in a transmitter/receiver that transmits and receives optical signals such as laser light in a communication system in which a plurality of transmitter/receivers are connected by optical fibers. The above communication system may be a communication system that performs short- or medium-distance communication such as within a data center or between data centers, or long-distance communication such as between cities. The transmitter/receiver is, for example, installed in a data center.

The above communication system may be a communication system that performs wireless transmission and reception of optical signals such as near-infrared light between mobile terminals such as smartphones and tablets. The above communication system may be a communication system that performs wireless transmission and reception of optical signals such as near-infrared light between a mobile terminal and an information processing device such as a personal computer.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

As described above, the present disclosure has the effect of improving heat dissipation and shortening the fall time during optical response and is useful for light detection elements in general.

### APPENDIX

The light detection element according to the present disclosure comprises a magnetic element including a first ferromagnetic layer, a second ferromagnetic layer, and a spacer layer sandwiched between the first ferromagnetic layer and the second ferromagnetic layer, an upper electrode in contact with a first surface of the first ferromagnetic layer opposite to the spacer layer, and a lower electrode in contact with a second surface of the second ferromagnetic layer opposite to the spacer layer, the lower electrode having a narrowed plan view shape in the area including a portion in contact with the second ferromagnetic layer, and including a heat sink layer having a thickness that functions as a heat sink, and the entire magnetic element including the upper electrode is covered with a thermal conductive insulating material.

By this configuration, the light detection element according to the present disclosure can reduce excess heat from metal parts around the magnetic element by narrowing the lower electrode, improving heat dissipation efficiency. Furthermore, the lower electrode has a heat sink layer, which efficiently exhausts heat accumulated in the magnetic element. Furthermore, by covering the entire magnetic element including the upper electrode with a thermal conductive insulating material, the heat dissipation efficiency of the entire magnetic element is increased. By improving the heat dissipation in this way, the light response performance can be improved, and particularly the fall time during the light response can be shortened.

In the light detection element according to the present disclosure, the narrowed width of the lower electrode may be smaller than the spot diameter of the irradiated light.

By this configuration, the light detection element of the present disclosure can suppress excess heat generation from the lower electrode by making the narrowed width of the lower electrode smaller than the irradiated light spot diameter, thereby allowing part of the irradiated light to pass through without irradiating the lower electrode.

The light detection element according to the present disclosure may be configured to include a substrate provided on the side of the lower electrode opposite to the magnetic element, and a layer provided between the lower electrode and the substrate and containing a thermal conductive insulating material that is the same as or different from the thermal conductive insulating material.

By this configuration, the light detection element of the present disclosure can effectively remove heat from the magnetic element by having a thermal conductive insulating material between the substrate and the lower electrode.

In the light detection element of the present disclosure, the upper electrode may be optically transparent.

By this configuration, the light detection element of the present disclosure can deliver light to the magnetic element by having the upper electrode transparent to light of the wavelength used.

In the light detection element of the present disclosure, the heat sink layer may have a thickness of 100 nm or more and 1000 nm or less.

By this configuration, the light detection element of the present disclosure can ensure the heat sink layer to have a sufficient thermal capacity as a heat bath.

In the light detection element of the present disclosure, the thermal conductive insulating material may include either or both AlN and AlON.

By this configuration, the light detection element of the present disclosure can improve heat dissipation by using an insulating material having high thermal conductivity as the thermal conductive insulating material and can also be made optically transparent.

In the light detection element of the present disclosure, the heat sink layer may include either or both of layers of Ru and Cu, or may include a laminated film of Cu and a metal other than Cu.

By this configuration, the heat sink layer of the light detection element of the present disclosure can withstand high temperature annealing at 400° C for a magnetic element such as an MTJ element.

In the light detection element of the present disclosure, the lower electrode includes a seed layer on the side in contact with the magnetic element, and the heat sink layer in contact with the surface of the seed layer opposite to the magnetic element, and the seed layer may include either or both of layers of Ru and Cu, or may include a laminated film of Cu and a metal other than Cu.

By this configuration, the seed layer of the light detection element of the present disclosure can withstand high temperature annealing at 400°C for a magnetic element such as, for example, an MTJ element.

The light detection element according to the present disclosure can improve heat dissipation and shorten the fall time during light response.

### Description of Reference Numerals and Signs

1 First ferromagnetic layer

1a Upper surface of first ferromagnetic layer

2 Second ferromagnetic layer

2a Lower surface of second ferromagnetic layer

3 Spacer layer

10 Magnetic element

11 Upper electrode

12 Lower electrode layer (seed layer)

12a Lower surface of seed layer

13, 13-1, 13-2 Heat sink layers

14 Insulating layer

15 Laminate

20, 120 Lower electrodes

20a, 120a Parts in contact with second ferromagnetic layer

21, 22 Connection regions (regions)

23 Narrowed portion

25 Insulator

31, 32 Thermal conductive insulating layers (thermal conductive insulating material)

40 Substrate

100, 200 Light detection elements

L Light

S Light spot

SW Width of narrowed portion

What is claimed is:

1. A light detection element comprising:
a magnetic element including a first ferromagnetic layer, a second ferromagnetic layer, and a spacer layer sandwiched between the first ferromagnetic layer and the second ferromagnetic layer;
an upper electrode in contact with a first surface of the first ferromagnetic layer opposite to the spacer layer; and
a lower electrode in contact with a second surface of the second ferromagnetic layer opposite to the spacer layer;
wherein the lower electrode has a narrowed plan view shape in an area including a portion in contact with the second ferromagnetic layer, and includes a heat sink layer having a thickness that functions as a heat sink, and the entire magnetic element including the upper electrode is covered with a thermal conductive insulating material.

2. The light detection element according to claim 1, wherein the narrowed width of the lower electrode is smaller than the spot diameter of the irradiated light.

3. The light detection element according to claim 1, further comprising a substrate on the side of the lower electrode opposite to the magnetic element, and a layer provided between the lower electrode and the substrate and containing a thermal conductive insulating material that is the same as or different from the thermal conductive insulating material.

4. The light detection element according to claim 1, wherein the upper electrode is optically transparent.

5. The light detection element according to claim 4, wherein the upper electrode is ITO, IZO, ZnO, or IGZO.

6. The light detection element according to claim 1, wherein the heat sink layer has a thickness of 100 nm or more and 1000 nm or less.

7. The light detection element according to claim 1, wherein the thermal conductive insulating material contains either or both AlN and AlON.

8. The light detection element according to claim 1, wherein the thermal conductivity of the thermal conductive insulating material is higher than that of at least one of the magnetic element, the upper electrode, and the lower electrode.

9. The light detection element according to claim 1, wherein the thermal conductivity of the thermal conductive insulating material is larger than 40 W/m·K.

10. The light detection element according to claim 1, wherein the heat sink layer contains either or both of layers of Ru and Cu, or contains a laminated film of Cu and a metal other than Cu.

11. The light detection element according to claim 1, wherein the heat sink layer is a laminated film of Ru, Cu, Ru, Cu, and Ru, a laminated film of Ru, Cu, Cu, and Ru, a laminated film of Cu having a face-centered cubic (fcc) crystal structure and Co having a body-centered cubic (bcc) crystal structure, a laminated film of Cu having an fcc crystal structure and Mo or W having a bcc crystal structure, a laminated film of Cu and Mo, a laminated film of Cu, Co, and Mo, or a laminated film of Cu, Co, and Mo having a bcc crystal structure.

12. The light detection element according to claim 1, wherein the lower electrode includes a seed layer on the side in contact with the magnetic element and the heat sink layer in contact with the surface of the seed layer opposite to the magnetic element, and the seed layer includes either or both of layers of Ru and Cu, or includes a laminated film of Cu and a metal other than Cu.

13. The light detection element according to claim 12, wherein the seed layer is Ru with a thickness of 50 nm.

14. The light detection element according to claim 12, wherein the seed layer is a laminated film of Ru, Cu, Ru, Cu, and Ru, a laminated film of Ru, Cu, Cu, and Ru, a laminated film of Cu having an fcc crystal structure and Co having a bcc crystal structure, a laminated film of Cu having an fcc crystal structure and Mo or W having a bcc crystal structure, a laminated film of Cu and Mo, a laminated film of Cu, Co, and Mo, or a laminated film of Cu, Co, and Mo having a bcc crystal structure.

15. The light detection element according to claim 1, wherein the first ferromagnetic layer contains at least any one of Co, Fe, or Ni.

16. The light detection element according to claim 1, wherein the first ferromagnetic layer is a CoFeB alloy, a laminate in which a CoFeB alloy layer is sandwiched between Fe layers, or a laminate in which a CoFeB alloy layer is sandwiched between CoFe layers.

17. The light detection element according to claim 1, wherein the spacer layer contains aluminum oxide, magnesium oxide, titanium oxide, or silicon oxide.

18. A method for manufacturing a light detection element comprising:
laminating a first thermal conductive insulating layer, a heat sink layer, a seed layer, a second ferromagnetic layer, a spacer layer, and a first ferromagnetic layer on a substrate;
annealing the laminated film comprising the second ferromagnetic layer, the spacer layer, and the first ferromagnetic layer at an annealing temperature of 250°C to 400°C;
processing the laminated film into a columnar laminate;
forming a second thermal conductive insulating layer to cover the side surfaces of the laminate;
forming an upper electrode layer on the first ferromagnetic layer and the second thermal conductive insulating layer;
processing the upper electrode layer into a column shaped or plate shaped upper electrode; and
embedding the second thermal conductive insulating layer around and above the upper electrode.

19. A communication system comprising a plurality of transmitter/receivers configured to transmit and receive optical signals,
wherein each of the transmitter/receivers includes a receiver having the light detection element according to claim 1.

20. The communication system according to claim 19, wherein the optical signals are near-infrared light.
